(19) United States
(12) Patent Application Publication
(10) Pub. No.: US 2025/0390809 A1
(43) Pub. Date: Dec. 25, 2025

(54) OPERATION MANAGEMENT SYSTEM AND OPERATION MANAGEMENT METHOD

(71) Applicant: Hitachi, Ltd., Tokyo (JP)

(72) Inventors: Takashi MATSUMOTO, Tokyo (JP); Tomohiro OTSU, Tokyo (JP)

(21) Appl. No.: 18/841,040

(22) PCT Filed: Feb. 16, 2023
(86) PCT No.: PCT/JP2023/005448

§ 371 Date: Apr. 9, 2025

(30) Foreign Application Priority Data
Mar. 17, 2022 (JP) 2022-042350

(51) Int. Cl. G06Q 10/0631; B60L 53/10; G01R 31/382; G01R 31/396

(52) U.S. Cl. CPC G06Q 10/0631; B60L 53/11; G01R 31/382; G01R 31/396

(57) ABSTRACT

Provided is an operation management system that reduces an increase in the life cycle cost of an EV that is caused by degradation of battery performance. To this end, an operation management system 1 for managing the operations of a plurality of EVs 3 powered by a battery includes an operation planning section 11 and an operation plan monitoring section 12. The operation planning section 11 creates an operation plan for causing each EV 3 to perform the work of traveling between locations. The operation plan monitoring section 12 monitors the operation of each EV 3 that is performed in accordance with the operation plan. According to the operating status of each EV 3, the operation plan monitoring section 12 determines whether each EV 3 is able to complete the operation plan. The operation planning section 11 re-creates the operation plan in such a manner that remaining work of traveling between locations which has not been performed by an EV 3 that is determined by the operation plan monitoring section 12 to be unable to complete the operation plan is reassigned to another EV 3 according to the remaining battery level of each EV 3.

### TECHNICAL FIELD

The present invention relates to an operation management system and an operation management method.

### BACKGROUND ART

For operation management of electric vehicles (hereinafter referred to as “EVs” (Electric Vehicles)), it is necessary to meet the needs of users while satisfying the travel distance constraints imposed by battery charging time and battery capacity.

Batteries account for a large proportion of the vehicle cost of EVs. In the case of large vehicles such as trucks, the cost of the batteries is particularly high because large-capacity batteries are used.

Further, when EVs are operated for a long period of time, degradation of battery performance becomes a problem. In general, as regards the EVs, the battery performance degrades more significantly than the vehicle main body, and the battery life is shorter than the vehicle life. Hence, the batteries of the EVs are replaced during the operation of the EVs. If the batteries are replaced frequently, the cost of battery replacement increases to increase the life cycle cost of the EV, and causes a disadvantage to the users.

Accordingly, proposed is a technology that takes into account EV energy consumption and EV performance degradation when creating an EV operation plan and suppresses EV performance degradation, particularly battery performance degradation (refer, for example, to Patent Document 1).

### PRIOR ART DOCUMENT

### Patent Document

Patent Document 1: JP-2021-2216-A

### SUMMARY OF THE INVENTION

### Problems to be Solved by the Invention

However, the above-mentioned conventional technology does not create the EV operation plan in consideration of unexpected events that may occur during the actual operation of an EV. The occurrence of an unexpected event may increase the power consumption of the EV, cause it to run out of power, and hinder the completion of the EV operation plan. It is possible to complete the EV operation plan by fast charging of a battery when the EV runs out of power. However, if the battery performance degrades due to fast charging and the battery needs to be replaced frequently, the cost of battery replacement increases to still increase the life cycle cost of the EV, and causes a disadvantage to the users.

The present invention has been made in view of above circumstances, and aims to provide an operation management system and an operation management method for reducing an increase in the life cycle cost of an EV that is caused by degradation of battery performance.

### Means for Solving the Problems

In order to solve the above-described problems, according to an aspect of the present invention, there is provided an operation management system that manages the operations of a plurality of vehicles powered by a battery. The operation management system includes an operation planning section and an operation plan monitoring section. The operation planning section creates an operation plan for causing each of the plurality of vehicles to perform work of traveling between locations. The operation plan monitoring section monitors operation of each vehicle that is performed based on the operation plan. The operation plan monitoring section determines whether each vehicle is able to complete the operation plan, based on operating status of each vehicle. The operation planning section re-creates the operation plan in such a manner that remaining work of traveling between locations which has not been performed by vehicles determined by the operation plan monitoring section to be unable to complete the operation plan is reassigned to the other vehicles according to the remaining battery level of each vehicle.

### Advantages of the Invention

The present invention makes it possible to reduce an increase in the life cycle cost of an EV that is caused by degradation of battery performance.

Problems, configurations, and advantages other than those described above will become apparent from the following description of embodiments for implementing the invention.

### BRIEF DESCRIPTION OF THE DRAWINGS

FIG. 1 is a block diagram illustrating an example of a configuration of an operation management system 1 according to a first embodiment.

FIG. 2 is a diagram illustrating an example of a configuration of a routing plan DB.

FIG. 3 is a diagram illustrating an example of a configuration of a charging plan DB.

FIG. 4 is a diagram illustrating an example of a configuration of an operation plan DB.

FIG. 5 is a flowchart (part 1) illustrating an example of a replanning process according to the first embodiment.

FIG. 6 is a flowchart (part 2) illustrating the example of the replanning process according to the first embodiment.

FIG. 7 is a diagram illustrating an example of operation plan data that is to be subjected to the replanning process according to the first embodiment.

FIG. 8 is a diagram illustrating an example of selection of a successor vehicle taking over remaining work in the replanning process according to the first embodiment.

FIG. 9 is a flowchart (part 1) illustrating an example of the replanning process according to a second embodiment.

FIG. 10 is a flowchart (part 2) illustrating the example of the replanning process according to the second embodiment.

FIG. 11 is a diagram illustrating an example of operation plan data that is to be subjected to the replanning process according to the second embodiment.

FIG. 12 is a diagram illustrating an example of selection of the successor vehicle taking over the remaining work in the replanning process according to the second embodiment.

FIG. 13 is a diagram illustrating an example of the hardware configuration of a computer that implements the operation management system.

### MODES FOR CARRYING OUT THE INVENTION

Embodiments of the present invention will now be described with reference to the accompanying drawings. The embodiments are illustrated by way of example for explaining the present invention. The following description of the embodiments is omitted and simplified as needed to clarify the explanation. The present invention can be implemented in various other embodiments. Unless otherwise specified, each component element may be singular or plural.

In a case where a plurality of component elements have the same or similar functions, they are sometimes described by adding different suffixes to the same reference symbol. Further, when there is no need to make a distinction between such plurality of component elements, they are sometimes described with the suffixes omitted.

The embodiments are sometimes described by explaining the processing that is performed by executing a program. In such an instance, a computing device executes the program by using a processor (e.g., a CPU (Central Processing Unit) or a GPU (Graphics Processing Unit)), and performs the processing defined by the program, by using storage resources (e.g., memories) and interface devices (e.g., communication ports). Hence, the subject of the processing performed by executing the program may be the processor. Similarly, the subject of the processing performed by executing the program may be a controller, an apparatus, a system, a computing device, or a node that has the processor. The subject of the processing performed by executing the program may be an arithmetic section, and may include a dedicated circuit for performing a specific process. Here, the dedicated circuit is, for example, an FPGA (Field Programmable Gate Array), an ASIC (Application Specific Integrated Circuit), a CPLD (Complex Programmable Logic Device), or a quantum computer.

The program may be installed on the computing device from a program source. The program source may be, for example, a program distribution server or a computing device-readable storage medium. In a case where the program source is a program distribution server, the program distribution server may include a processor and a storage resource for storing a distribution target program, and the processor included in the program distribution server may distribute the distribution target program to other computing devices. Further, the embodiments may be configured by implementing two or more programs as one program or by implementing one program as two or more programs.

In the following description, “XXXDB” refers to a database that stores the information (or data) “XXX.” In some cases, however, “XXXDB” refers to “XXX” itself, which is stored in “XXXDB.” DB (Data Base) is an example of a storage section.

In the following description of the embodiments, an operation plan describing an association indicating which vehicles will be operated on which routes in accordance with what schedule and indicating what schedule is to be applied to charging is assumed to have been created the day before an operation date. The operation plan can be created by using a well-known technology disclosed, for example, in Patent Document 1.

The technology disclosed in the present application is configured such that, if an unexpected event occurs while a vehicle is operating in accordance with a pre-created operation plan, and thus disables the vehicle to complete the work that is remaining (remaining work), the remaining work is taken over by another vehicle that is currently operating. A vehicle having enough battery power remaining to take over and complete the remaining work even after completing its own work is selected as the vehicle that will take over the remaining work.

### First Embodiment

The present embodiment is described below with reference to an example in which, if an “unexpected event” unforeseeable at the time of planning occurs during the operation of a vehicle (hereinafter referred to as an “EV” (Electric Vehicle)) powered by a battery charged the day before the operation, another EV in operation takes over the remaining work of the affected EV. Further, the present embodiment is also described with reference to another example in which, if one EV is unable to take over the remaining work and the remaining work can be divided into a plurality of remaining tasks, the plurality of remaining tasks obtained by division are taken over by two or more other EVs in operation.

The above-mentioned “unexpected event” may be, for example, a breakdown or accident of the EV (inability to continue work), a traffic jam due to an accident, a road closure (due, for instance, to weather or accidents), changes in operation plans (cancellation or addition), or a driver change (illness or sudden early departure). Specifically, if the EV is a logistics vehicle, the “unexpected event” may be redelivery upon absence of a recipient or sudden collection of goods received on the day of operation. If the EV is a taxi, the “unexpected event” may be an extraordinary long-distance transport. If the EV is a police patrol vehicle (patrol car), the “unexpected event” may be an emergency dispatch other than patrolling. The “unexpected event” is not limited to the above-mentioned ones, and may be any event that makes it impossible to complete the original operation plan.

If the “unexpected event” unforeseeable at the time of planning occurs, the EV's power consumption may increase more than expected, resulting in a lack of power and disrupting business operations. Further, while it is possible to continue the business operations by fast charging, fast charging accelerates the degradation of battery performance and increases the life cycle cost of the EV. The present embodiment makes it possible to complete business operations in the event of an “unexpected event” without causing the degradation of battery performance.

### (Configuration of Operation Management System 1)

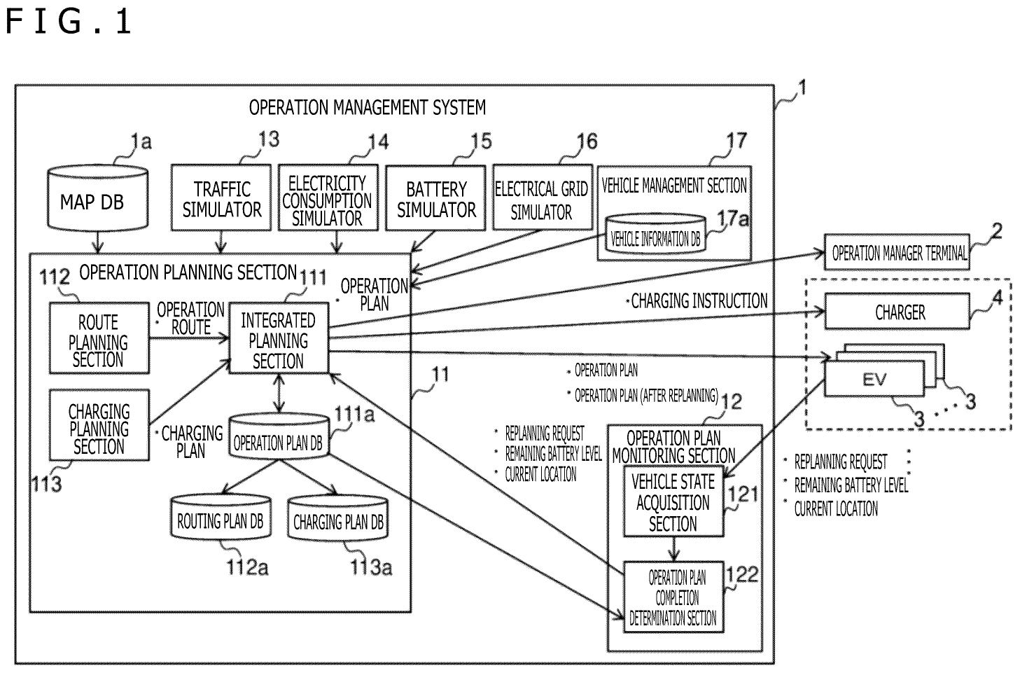

FIG. 1 is a block diagram illustrating an example of a configuration of an operation management system 1 according to the first embodiment. The operation management system 1 is connected to an operation manager terminal 2, as exemplified by a console equipped with a display, and to one or more combinations of a plurality of EVs 3 and a charger 4. A combination of the plurality of EVs 3 and the charger 4 is provided for each EV vehicle/charging station (hereinafter referred to as the “station”) such as a garage or a business office. The operation manager terminal 2 uses, for example, a screen to output information outputted from the operation management system 1. The EVs 3 are connected to the operation management system 1 to be able to wirelessly communicate with the operation management system 1, are operated in accordance with the operation plan for each EV 3 which is outputted from the operation management system 1, and transmit a current remaining battery level and a current location to the operation management system 1. The charger 4 receives power from an electrical grid in accordance with a charging instruction from the operation management system 1, and charges the EVs 3.

The operation management system 1 includes an operation planning section 11, an operation plan monitoring section 12, a map DB 1a, a traffic simulator 13, an electricity consumption simulator 14, a battery simulator 15, an electrical grid simulator 16, and a vehicle management section 17.

The map DB 1a stores map information including, for example, the “distance” between target locations connected by roads. The traffic simulator 13 simulates, for example, “traffic conditions” in each time slot regarding, for example, the roads connecting the target locations. The electricity consumption simulator 14 simulates, for example, the “required amount of electricity” that is consumed by the EVs 3 running on the roads connecting the target locations under the simulated traffic conditions. The “required amount of electricity” is calculated in reference to the speed and the travel route of the EVs 3 and the map information. The battery simulator 15 simulates, for example, the “remaining battery level,” the “predicted lifetime,” and the “predicted degradation” of a battery installed in the EVs 3 running on the roads connecting the target locations. The electrical grid simulator 16 simulates, for example, the amount and the price of electricity suppliable from the electrical grid to the EVs 3 in each time slot and a renewable energy supply time slot. The vehicle management section 17 has a vehicle information DB 17a that manages, for example, the “vehicle type” and the “battery type” of each EV 3 identified by a “vehicle ID.” The “vehicle type” and the “battery type” are taken into consideration in order to reduce the degradation of the battery and provide a longer battery life at the time of creating a routing plan DB 112a, a charging plan DB 113a, and an operation plan DB 111a, which will be described later, and at the time of re-creating the operation plan DB 111a.

It should be noted that some or all of the map DB 1a, the traffic simulator 13, the electricity consumption simulator 14, the battery simulator 15, the electrical grid simulator 16, and the vehicle management section 17 may be apparatuses external to the operation management system 1.

The operation planning section 11 includes an integrated planning section 111, a route planning section 112, a charging planning section 113, the operation plan DB 111a, the routing plan DB 112a, and the charging plan DB 113a.

The route planning section 112 creates the routing plan DB 112a that reduces the degradation of the battery and provides a longer battery life for the EV 3 by collective traveling between a plurality of locations on the route of a single operation plan. The routing plan DB 112a is created in accordance with, for example, “delivery instructions” and “freight specifications” received from a customer service system (not depicted), the “distance” based on the map DB 1a, the “traffic conditions” simulated by the traffic simulator 13, and the “required amount of electricity” and the “remaining battery level” simulated by the battery simulator 15.

### (Configuration of Routing Plan DB 112a)

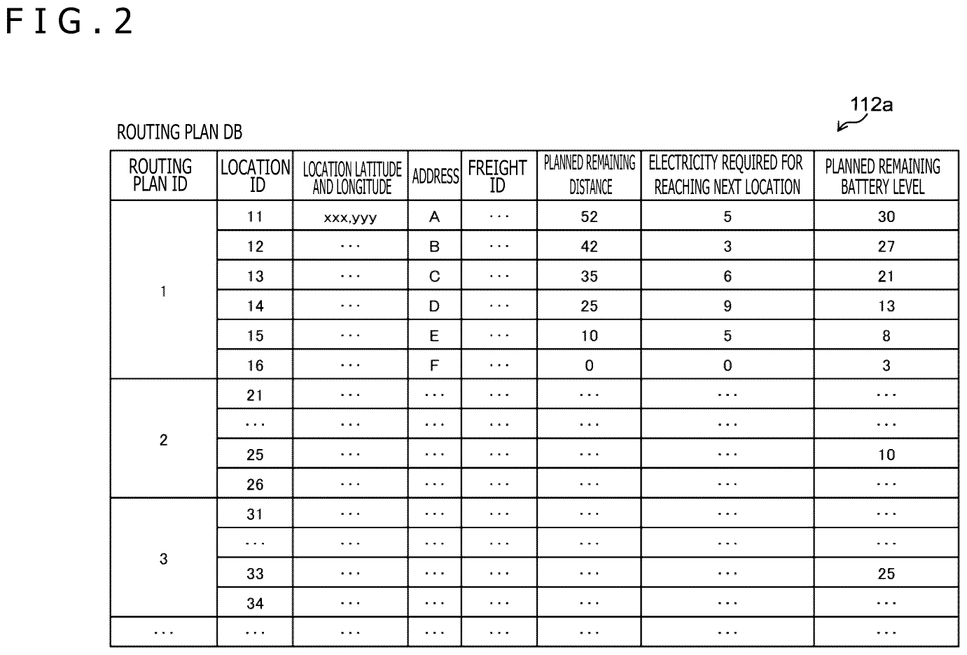

FIG. 2 is a diagram illustrating an example of the configuration of the routing plan DB 112a. The routing plan DB 112a has columns for “routing plan ID,” “location ID,” “location latitude and longitude,” “address,” “freight ID,” “planned remaining distance,” “electricity required for reaching next location,” and “planned remaining battery level.”

The “location ID,” the “location latitude and longitude,” and the “address” provide information regarding a location identified by the “location ID.” The “freight ID” provides identification information regarding freight that is to be collected at or delivered to a location identified by the “location ID,” and a plurality of freight IDs are arranged in the order of traveling of an EV 3. In a routing plan, the start and end locations of a route in one routing plan identified by the same “routing plan ID” may be identical with each other (a case where the EV 3 returns to a station where the EV 3 departed) or different from each other (a case where the EV 3 returns to a station different from the station where the EV 3 departed). The “address” and “freight ID” columns provide auxiliary information for identifying the locations and the purpose of traveling between the locations in a case where an operation management target is a delivery vehicle. However, the “address” and “freight ID” columns may be omitted.

The “planned remaining distance” indicates the distance from the end location to a location that is between the start and end locations in one routing plan identified by the “routing plan ID” and that is identified by the corresponding “location ID.” The “electricity required for reaching next location” indicates the amount of electricity required for the EV 3 to move to the next location from a location that is between the start and end locations in one routing plan identified by the “routing plan ID” and that is identified by the corresponding “location ID.” The “planned remaining battery level” indicates the minimum remaining battery level that the EV 3 should retain when it reaches a location identified by the “location ID,” in order to complete the routing plan identified by the “routing plan ID.” When displayed, the “electricity required for reaching next location” and the “planned remaining battery level” may be expressed in percentage to the total battery capacity or indicative of the actual amount of electricity.

The charging planning section 113 creates the charging plan DB 113a that reduces the degradation of the battery and provides each EV 3 with a longer battery life according to, for example, the “vehicle type” and the “battery type” of each EV 3, which are managed by the vehicle information DB 17a, the “charger ID” which identifies the charger 4 at the station, and the charging performance of the charger 4.

### (Configuration of Charging Plan DB 113a)

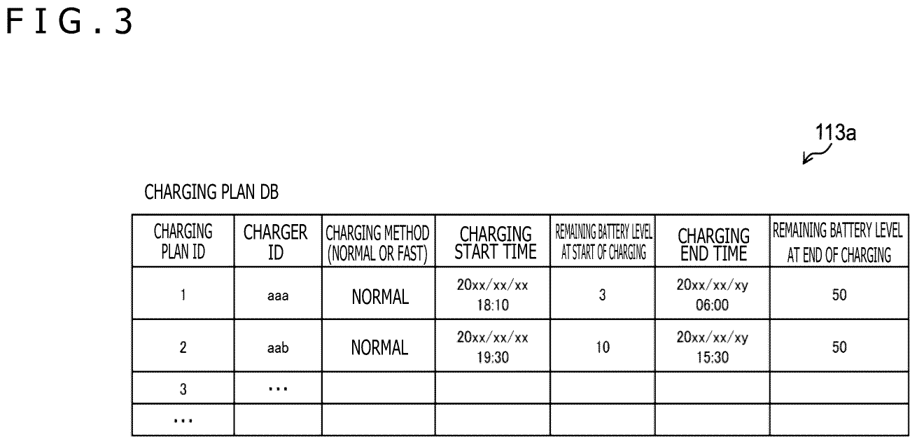

FIG. 3 is a diagram illustrating an example of a configuration of the charging plan DB 113a. The charging plan DB 113a has columns for “charging plan ID,” “charger ID,” “charging method (normal or fast),” “charging start time,” “remaining battery level at start of charging,” “charging end time,” and “remaining battery level at end of charging.”

The “charging plan ID” is information for identifying a charging plan. The “charger ID” is identification information regarding the charger used in a charging plan identified by the “charging plan ID.” The “charging method (normal or fast)” indicates whether the charging speed specified in the charging plan identified by the “charging plan ID” is normal charging or fast charging. The “charging start time” indicates the start date and time of charging that are specified in the charging plan identified by the “charging plan ID.” The “remaining battery level at the start of charging” is the remaining battery level at start of charging of the battery to be charged according to the charging plan identified by the “charging plan ID.” The “charging end time” is the end date and time of charging that are specified in the charging plan identified by “charging plan ID.” The “remaining battery level at end of charging” is the remaining battery level at the end of charging of the battery to be charged according to the charging plan identified by the “charging plan ID.” When displayed, the “remaining battery level at start of charging” and the “remaining battery level at end of charging” may be expressed in percentage to the total battery capacity or indicative of the actual amount of electricity.

The integrated planning section 111 creates the operation plan DB 111a by determining the routing plan DB 112a and the charging plan DB 113a that are to be assigned to each EV 3 in accordance with, for example, the “delivery instructions” from the customer service system (not depicted). The integrated planning section 111 causes the operation manager terminal 2 to output the operation plan DB 111a, the routing plan DB 112a, and the charging plan DB 113a.

### (Configuration of Operation Plan DB 111a)

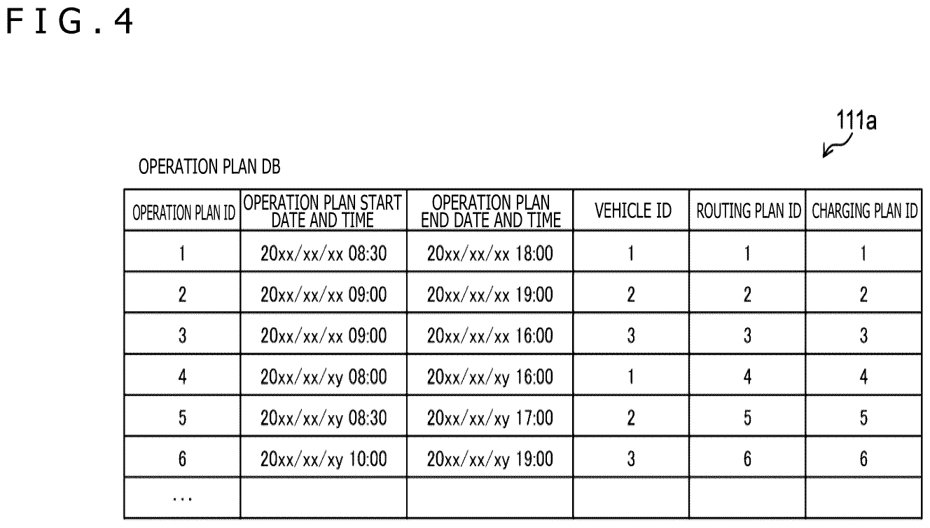

FIG. 4 is a diagram illustrating an example of a configuration of the operation plan DB 111a. The operation plan DB 111a has columns for “operation plan ID,” “operation plan start date and time,” “operation plan end date and time,” “vehicle ID,” “routing plan ID,” and “charging plan ID.”

The “operation plan ID” is information for identifying an operation plan. The “operation plan start date and time” is the start date and time specified in the operation plan identified by the “operation plan ID.” The “operation plan end date and time” is the end date and time specified in the operation plan identified by the “operation plan ID.” The “vehicle ID,” the “routing plan ID,” and the “charging plan ID” are the IDs of the EV 3, the routing plan, and the charging plan associated with the operation plan that specifies the “operation plan start date and time” and the “operation plan end date and time” and that is identified by the “operation plan ID.”

The operation plan monitoring section 12 includes a vehicle state acquisition section 121 and an operation plan completion determination section 122. The vehicle state acquisition section 121 receives, repeatedly at regular intervals, operating status, such as the remaining battery level of each battery and the current location, from each EV 3 operating according to the operation plan. Further, the vehicle state acquisition section 121 may receive a replanning request concerning the operation plan that is transmitted from the EV 3 at the discretion of the driver (operator) of each EV 3. For example, if the driver is unable to complete the remaining portion of the operation plan due to poor physical condition, the driver can transmit a replanning request from the EV 3 on his/her own will.

Upon each receipt of the latest remaining battery level and the current location from each EV 3, the operation plan completion determination section 122 determines, based on the operation plan DB 111a, whether the corresponding EV 3 is able to complete the operation plan with the latest remaining battery level and the current location. If it is determined that the corresponding EV 3 is unable to complete the operation plan with the latest remaining battery level and the current location, the operation plan completion determination section 122 transmits a replanning request concerning the operation plan, the latest remaining battery level, and the current location to the integrated planning section 111.

Further, upon receiving a replanning request concerning the operation plan from an EV 3 together with the latest remaining battery level and the current location, the operation plan completion determination section 122 determines that the EV 3 is unable to complete the operation plan, and transmits the replanning request, the latest remaining battery level, and the current location to the integrated planning section 111.

Upon receiving the replanning request concerning the operation plan, the latest remaining battery level, and the current location, the integrated planning section 111 performs a replanning process to change the operation plan as described later. The integrated planning section 111 not only causes the operation manager terminal 2 to output the result of the replanning process performed to change the operation plan, but also transmits the operation plan obtained by replanning to the corresponding EV 3 and causes it to operate in accordance with the new operation plan.

### (Replanning Process According to First Embodiment)

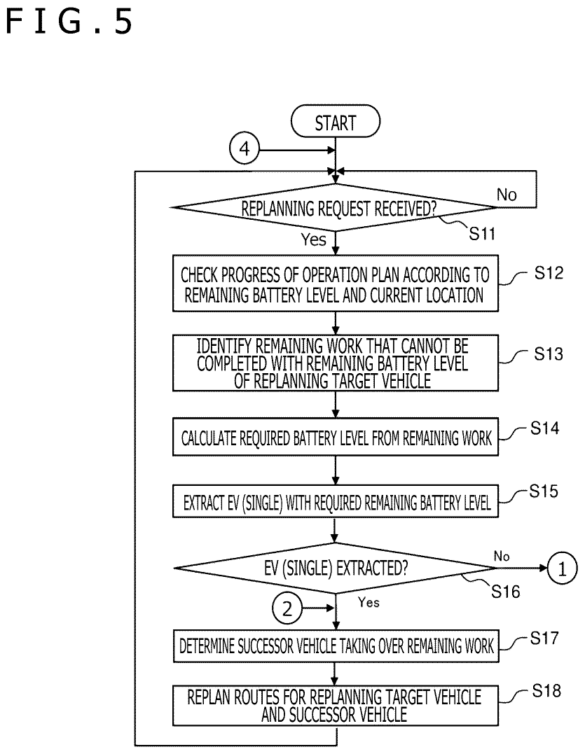

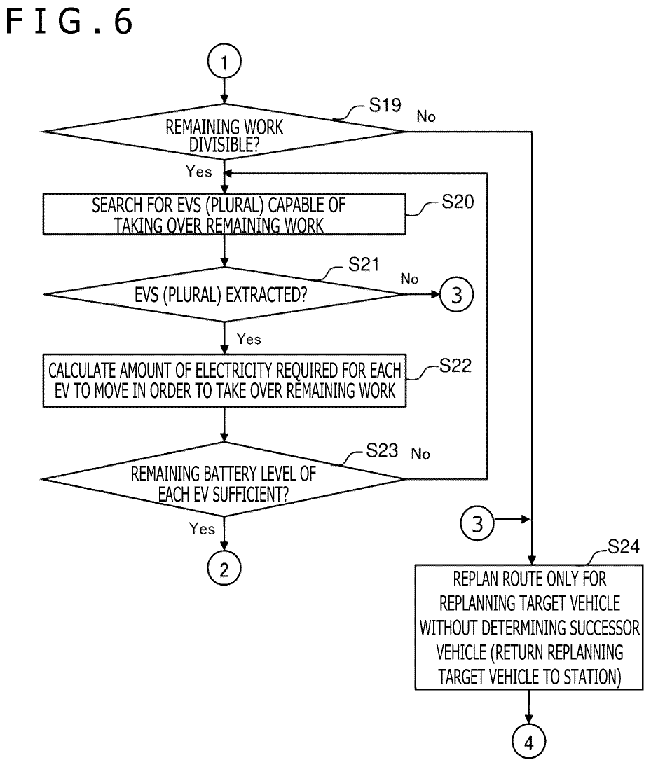

FIGS. 5 and 6 are flowcharts illustrating an example of the replanning process according to the first embodiment. The replanning process is performed in a case where the operation plan needs to be subjected to replanning because of an “unexpected event” encountered by an EV 3 operating according to the operation plan DB 111a that was created the day before the operation.

First, in step S11, the integrated planning section 111 determines whether it has received a replanning request concerning the operation plan of an EV 3 (hereinafter referred to as the “replanning target vehicle”) that is determined by the operation plan completion determination section 122 to be unable to complete the operation plan. If the integrated planning section 111 has received the replanning request (“YES” in step S11), the processing proceeds to step S12. On the other hand, if the integrated planning section 111 has not received the replanning request (“NO” in step S11), the processing repeats step S11.

In step S12, the integrated planning section 111 performs a simulation based on the remaining battery level and the current location of the replanning target vehicle, and thus checks the progress of the operation plan according to the remaining battery level and current location of the replanning target vehicle, which are received in step S11 together with the replanning request.

Next, in step S13, the integrated planning section 111 performs a simulation based on the remaining battery level and the current location of the replanning target vehicle, and based on the progress of the operation plan checked in step S13, identifies, as remaining work, the work (traveling to locations) that cannot be completed with the remaining battery level of the replanning target vehicle. It is assumed that the remaining battery level in this instance excludes the remaining battery level required for the replanning target vehicle to move to the station from which the replanning target vehicle has departed or move to the nearest station. It should be noted that, in a case where the replanning request received in step S11 is based on a replanning request issued by the driver of the replanning target vehicle, the integrated planning section 111 identifies, in step S13, all uncompleted tasks (unreached locations) as the remaining work without regard to the remaining battery level of the replanning target vehicle.

In steps S12 and S13, simulations are performed by use of the simulators, such as the traffic simulator 13 or the electricity consumption simulator 14, in order to check the progress of the operation plan and identify the remaining work. This makes it possible to accurately identify the remaining work. More specifically, when the current remaining battery level of the EV 3 falls below the planned remaining battery level stored in the operation plan DB 111a, the EV 3 is unable to travel to all the locations subsequent to the current location of the EV 3. However, in some cases, the EV 3 may be able to travel to some of the subsequent locations and return to the station. When the above-described simulations are performed, the efficiency of battery utilization by the EV 3 can be improved by not identifying all the tasks of traveling to the locations subsequent to the current location as the remaining work, but by doing the length of the route for traveling to the remaining locations and the required amount of electricity wherever possible and thus reducing the amount of remaining work to be taken over by other EVs 3.

Further, for the purpose of checking the progress of the operation plan in step S12 and identifying the remaining work in step S13, a simple calculation method may be used to compare the planned remaining battery level stored in the operation plan DB 111a with the current location and the remaining battery level of the EV 3, and identify, as the remaining work, the whole work of traveling between the locations subsequent to a location where the remaining battery level has fallen below the planned remaining battery level.

Next, in step S14, the integrated planning section 111 calculates the amount of electricity required to complete the remaining work identified in step S13. Subsequently, in step S15, the integrated planning section 111 attempts to extract a different EV 3 (single) that is currently operating with a current actual remaining battery level sufficient to be able to complete its own work and take over the remaining work of the replanning target vehicle, including the movement required for takeover.

Then, in step S16, the integrated planning section 111 determines whether an EV 3 (single) capable of taking over the remaining work of the replanning target vehicle has been extracted in step S15. If an EV 3 (single) capable of taking over the remaining work of the replanning target vehicle has been extracted by the integrated planning section 111 (“YES” in step S16), the processing proceeds to step S17. On the other hand, if such an EV 3 has not been extracted (“NO” in step S16), the processing proceeds to step S19 (FIG. 6).

In step S17, the integrated planning section 111 determines, as a successor vehicle, one EV 3 that has been extracted in step S16 for being capable of taking over the remaining work of the replanning target vehicle. Next, in step S18, the integrated planning section 111 replans the routes of the replanning target vehicle and the successor vehicle. Specifically, the integrated planning section 111 re-creates the operation plan for moving the replanning target vehicle to a departure station or the nearest station via a taking-over location. Further, the integrated planning section 111 re-creates the operation plan for the successor vehicle for the purpose of completing the remaining work of the successor vehicle and the taken-over work via the taking-over location in such a manner as to reduce the degradation of the battery of the EV 3 and provide a longer battery life. When step S18 is completed by the integrated planning section 111, the processing returns to step S11.

It should be noted that the taking-over location for the work is in one of the following, for example, three patterns. In the first pattern, the successor vehicle moves to the current location of the replanning target vehicle, and the amount of electricity required for the movement of the successor vehicle needs to be considered in steps S15 and S18. In the second pattern, the successor vehicle and the replanning target vehicle both move to the same station, and the amount of electricity required for the movement of the vehicles to the respective stations needs to be considered in steps S15 and S18. In the third pattern, the successor vehicle and the replanning target vehicle both move to an appropriate location (e.g., an intermediate location), and the amount of electricity required for the movement of the vehicles to the appropriate location needs to be considered in steps S15 and S18.

Next, in step S19, the integrated planning section 111 determines whether the remaining work identified in step S13 is divisible and thus completable by a plurality of EVs 3. “Divisible” signifies that the remaining work includes a plurality of tasks (traveling to locations). If it is determined by the integrated planning section 111 that the remaining work is divisible (“YES” in step S19), the processing proceeds to step S20. On the other hand, if it is determined by the integrated planning section 111 that the remaining work is not divisible (“NO” in step S19), the processing proceeds to step S24.

In step S20, as regards the remaining work determined in step S19 to be divisible, the integrated planning section 111 attempts to extract EVs 3 (plural) that are currently operating with a planned remaining battery level sufficient to be able to complete their own work and take over the remaining work divided into a plurality of tasks, including the movement required for takeover.

Next, in step S21, the integrated planning section 111 determines whether EVs 3 (plural) capable of taking over the remaining work of the replanning target vehicle, which is divided into the plurality of tasks, have been extracted in step S20. If the EVs 3 (plural) capable of taking over the remaining work of the replanning target vehicle, which is divided into the plurality of tasks, have been extracted by the integrated planning section 111 (“YES” in step S21), the processing proceeds to step S22. On the other hand, if such EVs 3 have not been extracted (“NO” in step S21), the processing proceeds to step S24.

In step S22, the integrated planning section 111 calculates each amount of electricity required for each EV 3 to move in order to take over the remaining work divided into the plurality of tasks. The taking-over location where the remaining work divided into the plurality of tasks is to be taken over by each EV 3 is the same as the above-mentioned taking-over location. Each amount of electricity required for each EV 3 to move in order to take over the remaining work is the amount of electricity required for each EV 3 to move to a location where, for example, the work and the freight are to be taken over.

Next, in step S23, the integrated planning section 111 determines whether the current actual remaining battery level of each EV 3 is sufficient to include, as a margin, the amount of electricity required for each EV 3, which has been calculated in step S22. More specifically, the integrated planning section 111 determines whether the current actual remaining battery level of each EV 3 is sufficient to complete its own remaining work and move to a location where, for example, the work and the freight are to be taken over. If it is determined by the integrated planning section 111 that the current actual remaining battery level of each EV 3 is sufficient (“YES” in step S23), the processing returns to step S17 (FIG. 5). On the other hand, if such a battery level is determined not to be sufficient (“NO” in step S23), the processing returns to step S20.

When the processing returns to step 20, the integrated planning section 111 attempts to extract other EVs 3 (plural) with a planned remaining battery level sufficient to be able to take over each of the remaining tasks determined as a result of division, by using a different division pattern for the remaining work determined in step S19 to be divisible.

In step S24, since the successor vehicle cannot be determined, the integrated planning section 111 replans the route only for the replanning target vehicle, and returns the replanning target vehicle to the departure station or the nearest station. The operation plan is re-created (or revised) to recharge the battery of the replanning target vehicle returned to the station in step S24 or change its driver and cause the replanning target vehicle to resume its work and complete the remaining work.

Alternatively, the operation planning section 11 may reassign a portion of the remaining work to other EVs 3 according to the remaining battery level of each EV 3, and re-create the operation plan in such a manner that the remaining work other than the above-mentioned portion is performed by the EV 3 itself that is determined to be unable to complete the operation plan.

### Specific Examples of First Embodiment

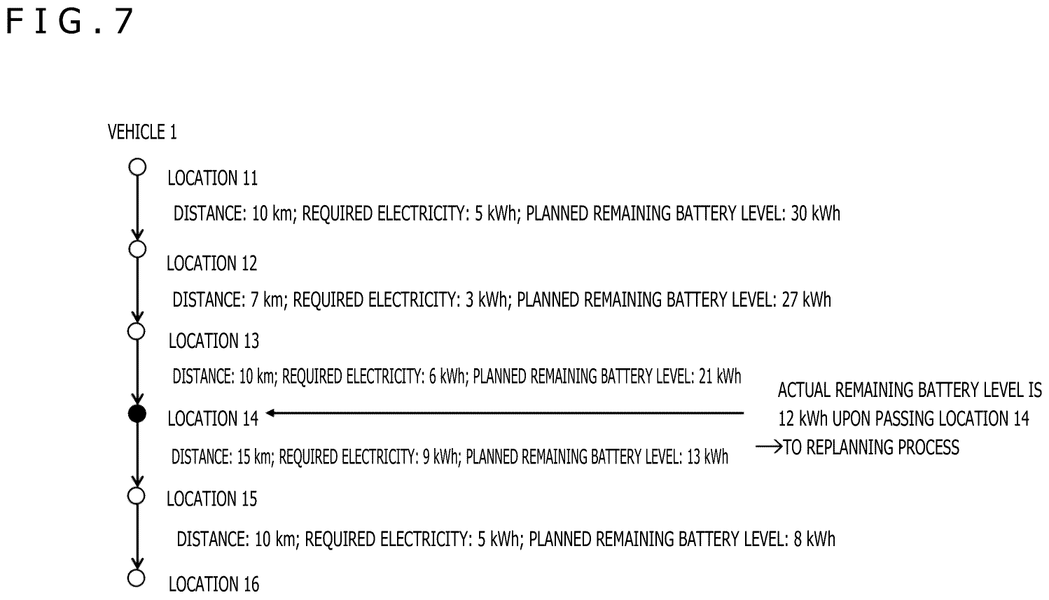

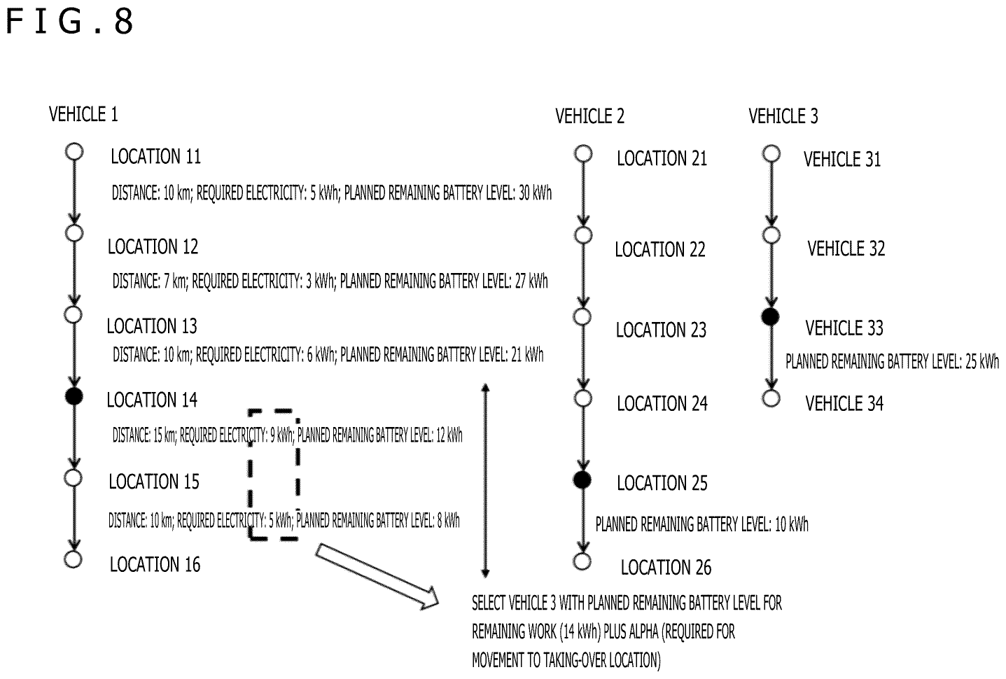

The following describes specific examples of operation plan data to be subjected to the replanning process in the present embodiment and selection of a successor vehicle taking over the remaining work. FIG. 7 is a diagram illustrating an example of operation plan data that is to be subjected to the replanning process according to the first embodiment. FIG. 8 is a diagram illustrating an example of selection of the successor vehicle taking over the remaining work in the replanning process according to the first embodiment.

As depicted in FIG. 7, it is assumed that there is an operation plan (with an operation plan ID of 1) in which a routing plan with a routing plan ID of 1 is assigned to a vehicle with a vehicle ID of 1. It is further assumed that the actual remaining battery level of an EV 3 with the vehicle ID of 1 is 12 kWh when the EV 3 is operated according to the above-mentioned operation plan to pass a traveling location with a location ID of 14. The operation plan completion determination section 122 (FIG. 1) references the operation plan DB 111a and the routing plan DB 112a to confirm that the actual remaining battery level is lower than a planned remaining battery level of 13 kWh at the time of passing the traveling location with the location ID of 14 in the routing plan with the routing plan ID of 1. Since the EV 3 is unable to complete the operation plan with the actual remaining battery level of 12 kWh, the operation plan completion determination section 122 requests the integrated planning section 111 (FIG. 1) to replan the route of the EV 3.

As depicted in FIG. 8, the integrated planning section 111 identifies locations with location IDs of 15 and 16 as the remaining work of the vehicle with the vehicle ID of 1, and calculates the required electricity as expressed in the equation (9+5)=14 kWh. Then, the integrated planning section 111 extracts, as a candidate successor vehicle, a different EV 3 with a vehicle ID of 3 that has a planned remaining battery level of 14 kWh or higher at the current traveling location. The integrated planning section 111 acquires the actual remaining battery level of the EV 3 with the vehicle ID of 3 through the operation plan monitoring section 12, and determines whether the acquired actual remaining battery level, including the electricity required for the movement required for takeover, is sufficient to take over the remaining work of the EV 3 with the vehicle ID of 1. If the actual remaining battery level of the EV 3 with the vehicle ID of 3 is sufficient to take over the remaining work of the EV 3 with the vehicle ID of 1, the integrated planning section 111 determines the EV 3 with the vehicle ID of 3 as the successor vehicle that takes over the remaining work of the EV 3 with the vehicle ID of 1.

### Second Embodiment

The following description of the second embodiment is mainly focused on the differences from the first embodiment. Component elements and processes similar to those of the first embodiment are designated by the same reference symbols as the corresponding ones of the first embodiment and will not be redundantly described.

The second embodiment is described below with reference to an example in which the remaining work of a plurality of EVs having experienced “unexpected events” during operation is to be taken over by another EV that is in operation. Further, the following description of the second embodiment also includes an example in which remaining work of the plurality of EVs are to be taken over by two or more EVs in operation in a case where the remaining work of the plurality of EVs cannot be fully taken over by one EV.

### (Replanning Process According to Second Embodiment)

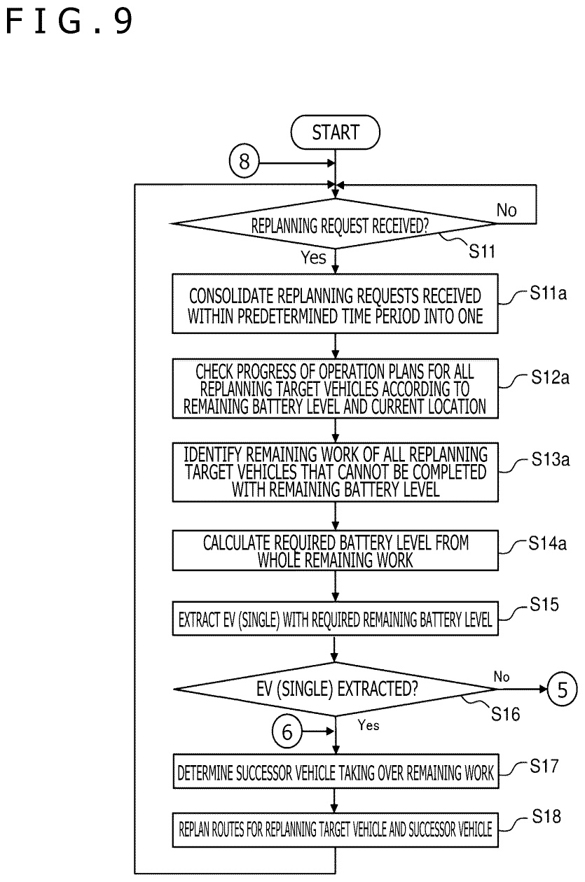

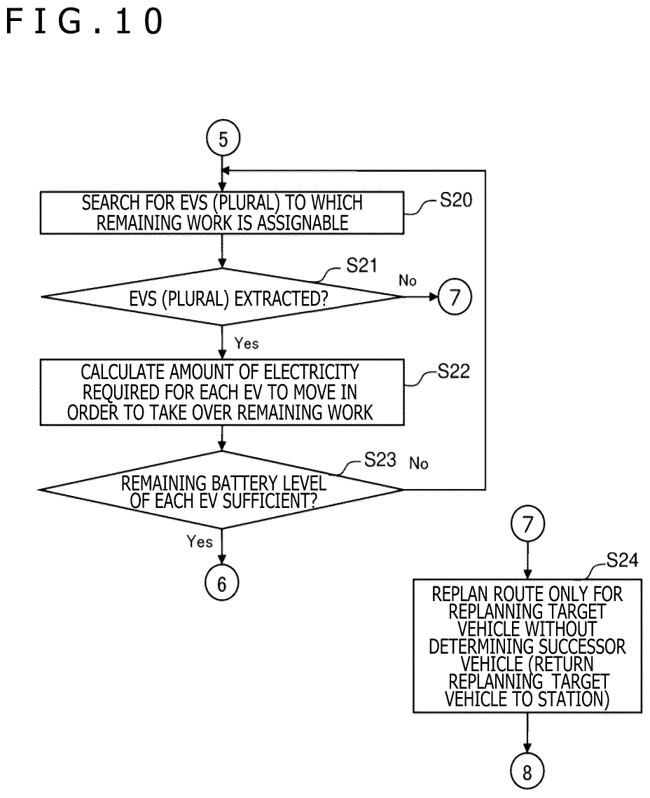

FIGS. 9 and 10 are flowcharts illustrating an example of the replanning process according to the second embodiment. The following description of the second embodiment is mainly focused on the differences from the first embodiment. Processing steps similar to those in the replanning process (FIGS. 5 and 6) according to the first embodiment are designated by the same reference symbols as the corresponding ones of the first embodiment and will not be redundantly described.

In step S11a, the integrated planning section 111 consolidates replanning requests received in step S11 within a predetermined time period into one.

Next, in step S12a, the integrated planning section 111 checks the progress of the operation plans for all replanning target vehicles consolidated in step S11a, according to the remaining battery level and the current location. Subsequently, in step S13a, the integrated planning section 111 identifies the remaining work of all the replanning target vehicles that cannot be completed with the remaining battery level. Then, in step S14a, the integrated planning section 111 calculates the required amount of electricity from every remaining work identified in step S13a.

The replanning process of the second embodiment differs from the replanning process of the first embodiment in that the former does not perform step S19 (FIG. 6) to determine whether “the remaining work is divisible.” The reason is that the identified remaining work is a collection of each remaining work of a plurality of replanning target vehicles and is thus divisible. If the answer to the query in step S16 is “NO,” the replanning process of the second embodiment proceeds to step S20.

Further, the replanning process of the second embodiment proceeds to step S24 only when the answer to the query in step S21 is “NO.”

Performing the replanning process of the present embodiment makes it possible to achieve an m-to-l takeover in which the remaining work of a plurality of EVs (m EVs) affected by “unexpected events” during operation is taken over by one other EV in operation. Moreover, in a case where the remaining work cannot be taken over by one EV, performing the replanning process of the present embodiment makes it possible to achieve an m-to-n takeover in which the remaining work of a plurality of EVs (m EVs) is taken over by two or more other EVs (n EVs) in operation.

### Specific Examples of Second Embodiment

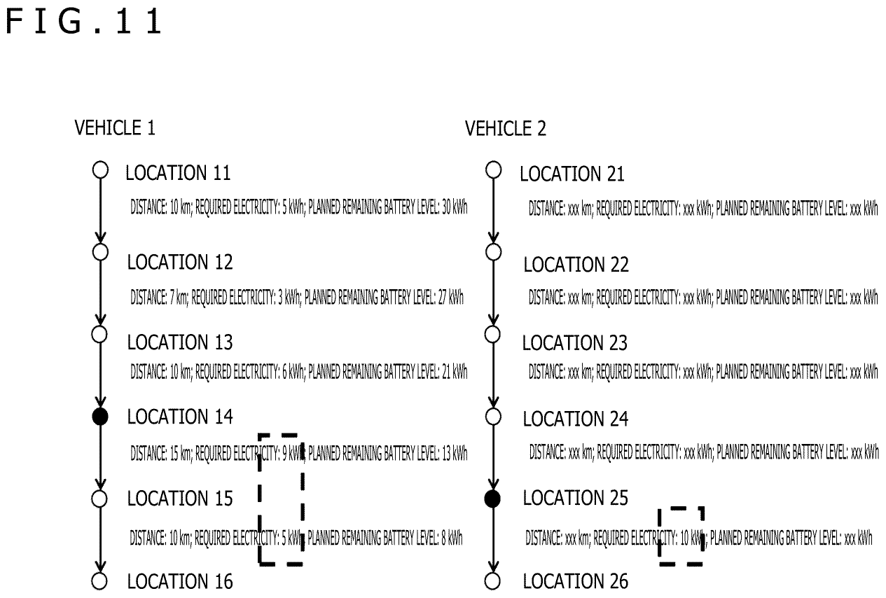

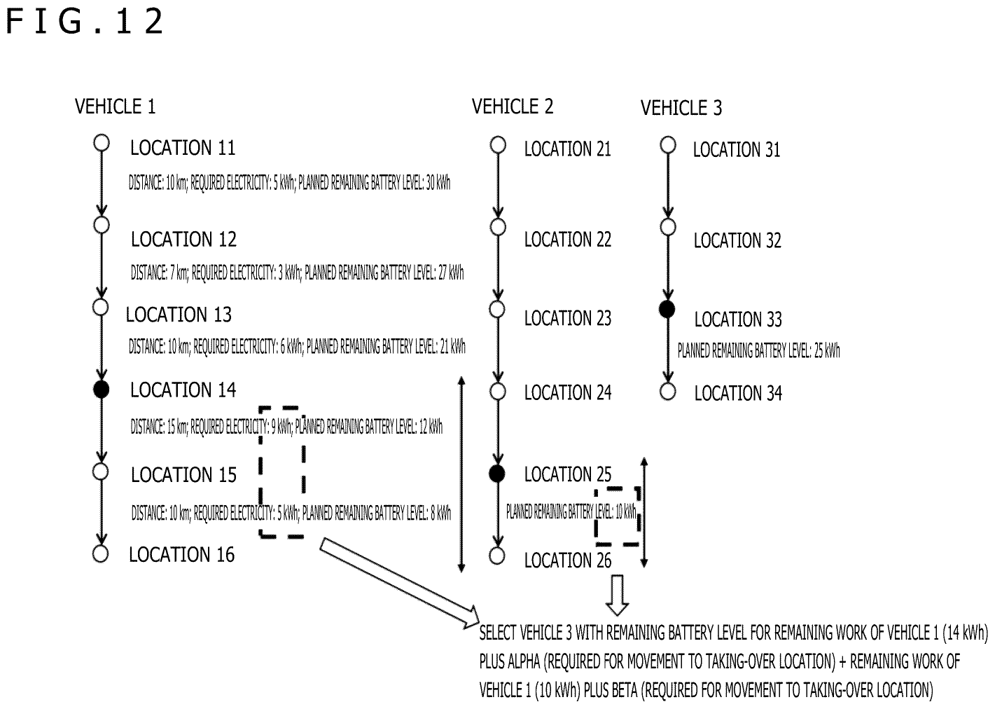

The following describes specific examples of operation plan data to be subjected to the replanning process in the present embodiment and selection of a successor vehicle taking over the remaining work. FIG. 11 is a diagram illustrating an example of operation plan data that is to be subjected to the replanning process according to the second embodiment. FIG. 12 is a diagram illustrating an example of selection of the successor vehicle taking over the remaining work in the replanning process according to the second embodiment.

As depicted in FIG. 11, it is assumed that there is an operation plan (with the operation plan ID of 1) in which a routing plan with the routing plan ID of 1 is assigned to a vehicle with the vehicle ID of 1, and that there is an operation plan (with an operation plan ID of 2) in which a routing plan with a routing plan ID of 2 is assigned to a vehicle with a vehicle ID of 2.

An EV 3 with the vehicle ID of 1 is the same as that depicted in FIG. 7. It is assumed that the actual remaining battery level of an EV 3 with the vehicle ID of 2 is 9 kWh when the EV 3 is operated according to an operation plan (with the operation plan ID of 2) to pass a traveling location with a location ID of 25. The operation plan completion determination section 122 (FIG. 1) references the operation plan DB 111a and the routing plan DB 112a to confirm that the actual remaining battery level is lower than a planned remaining battery level of 10 kWh at the time of passing the traveling location with the location ID of 25 in the routing plan with the routing plan ID of 2. Since the EV 3 is unable to complete the operation plan with the actual remaining battery level of 9 kWh, the operation plan completion determination section 122 requests the integrated planning section 111 (FIG. 1) to replan the route of the EV 3.

When performing route replanning, if the replanning requests concerning the EVs 3 with vehicle IDs of 1 and 2 are close to each other within a predetermined time period, the integrated planning section 111 determines a successor vehicle that takes over the remaining work of both of these EVs 3.

As depicted in FIG. 12, the integrated planning section 111 identifies the locations with the location IDs of 15 and 16 as the remaining work of the vehicle with the vehicle ID of 1, and calculates the required electricity as expressed in the equation (9+5)=14 kWh. Further, the integrated planning section 111 identifies the location with a location ID of 26 as the remaining work of the vehicle with the vehicle ID of 2, and calculates the required electricity of 10 kWh. The integrated planning section 111 identifies that the amount of electricity required for completing the remaining work of all the replanning target vehicles is as expressed in the equation (14+10)=24 kWh.

Subsequently, the integrated planning section 111 extracts, from among the other EVs 3, an EV with the vehicle ID of 3 whose planned remaining battery level at the current traveling location is 24 kWh or higher, as a candidate successor vehicle. The integrated planning section 111 acquires the actual remaining battery level of the EV 3 with the vehicle ID of 3 through the operation plan monitoring section 12, and determines whether the acquired actual remaining battery level, including the electricity required for the movement required for takeover, is sufficient to take over the remaining work of the EVs 3 with the vehicle IDs of 1 and 2. In a case where the actual remaining battery level of the EV 3 with the vehicle ID of 3 is sufficient to take over the remaining work of the EVs 3 with the vehicle IDs of 1 and 2, the integrated planning section 111 determines the EV 3 with the vehicle ID of 3 as a successor vehicle that takes over the remaining work of both of the EVs 3 with the vehicle IDs of 1 and 2.

### (Hardware of Computer 5000)

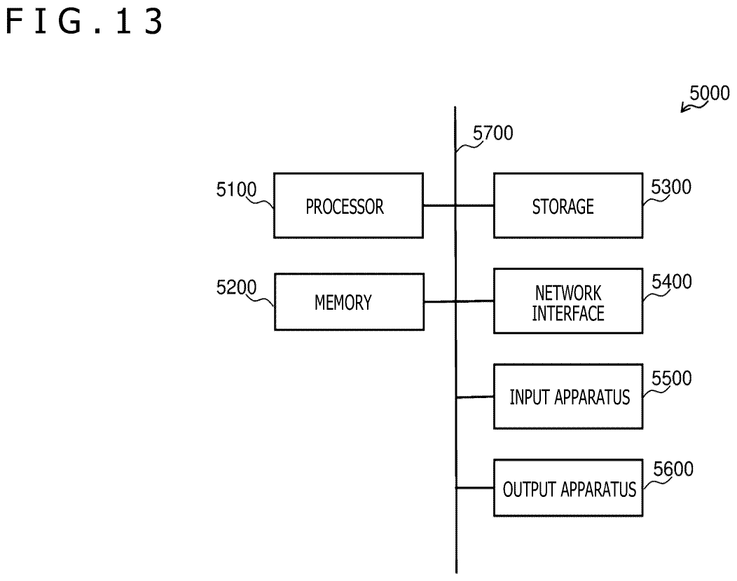

FIG. 13 is a diagram illustrating an example of the hardware configuration of a computer 5000 that implements the operation management system 1.

The computer 5000 is a general-purpose computer that includes a processor 5100, a memory 5200, a storage 5300, a network interface 5400, an input apparatus 5500, and an output apparatus 5600, which are interconnected through an internal communication line 5700 such as a bus.

The processor 5100 controls the operation of the entire computer 5000. The memory 5200 includes, for example, a volatile semiconductor memory, and is used as a work memory for the processor 5100. The storage 5300 includes a large-capacity nonvolatile storage device, such as a hard disk drive, an SSD (Solid State Drive), or a flash memory, and is used to store various kinds of programs and data. Executable programs stored in the storage 5300 are loaded into the memory 5200 as needed or for starting up the computer 5000. The executable programs loaded into the memory 5200 are executed by the processor 5100 to implement various functions of the operation management system 1.

Alternatively, the executable program may be recorded on a non-transitory recording medium, read from the non-transitory recording medium by a medium reading device, and loaded into the memory 5200. Still alternatively, the executable program may be obtained from an external computer through a network and loaded into the memory 5200.

The network interface 5400 is an interface device for connecting the computer 5000 to a network. The network interface 5400 includes, for example, a NIC (Network Interface Card) for a wired LAN (Local Area Network) or a wireless LAN.

The input apparatus 5500 includes, for example, a keyboard and a pointing device such as a mouse, and is used by a user to input various instructions and information to the computer 5000. The output apparatus 5600 includes, for example, a display device, such as a liquid-crystal display or an organic EL (Electro Luminescence) display, and an audio output device, such as a speaker, and is used to present relevant information to the user when necessary.

The present invention is not limited to the foregoing embodiments, and extends to various modifications. For example, the foregoing embodiments have been described in detail to facilitate the understanding of the present invention, and are not limited to configurations including all the described component elements. Further, as long as there is no contradiction, some component elements of an embodiment may be replaced by the component elements of another embodiment, and the component elements of an embodiment may be added to the component elements of another embodiment. Moreover, some component elements of each embodiment may be subjected to the addition of component elements, deleted, replaced, integrated, or dispersed. Furthermore, the component elements and processes described in conjunction with the embodiments may be appropriately distributed, integrated, or replaced based on processing efficiency or implementation efficiency.

### DESCRIPTION OF REFERENCE SYMBOLS

1: Operation management system
5000: Computer

1. An operation management system for managing operations of a plurality of vehicles powered by a battery, the operation management system comprising:
an operation planning section that creates an operation plan for causing each of the plurality of vehicles to perform work of traveling between locations;
an operation plan monitoring section that monitors the operation of each vehicle that is performed in accordance with the operation plan,
wherein, according to operating status of each vehicle, the operation plan monitoring section determines whether each vehicle is able to complete the operation plan, and
the operation planning section re-creates the operation plan in such a manner that remaining work of traveling between locations which has not been performed by a vehicle that is determined by the operation plan monitoring section to be unable to complete the operation plan is reassigned to another vehicle according to a remaining battery level of each vehicle.

2. The operation management system according to claim 1,
wherein, according to the remaining battery level and a current location of each vehicle that are received from each vehicle, the operation plan monitoring section determines whether each vehicle is able to complete the operation plan.

3. The operation management system according to claim 2,
wherein the operation plan includes a planned remaining battery level of the battery that is required for each vehicle to complete the operation plan at a time of reaching each location, and,
when the remaining battery level of each vehicle that is received from each vehicle is lower than the planned remaining battery level, the operation plan monitoring section determines that each vehicle is unable to complete the operation plan.

4. The operation management system according to claim 1,
wherein, upon receiving a replanning request concerning the operation plan that is transmitted from each of the plurality of vehicles in accordance with an instruction from a driver of each vehicle, the operation plan monitoring section determines that the vehicle from which the replanning request has been transmitted is unable to complete the operation plan.

5. The operation management system according to claim 1,
wherein the operation planning section performs a simulation based on the remaining battery level and a current location of each of the plurality of vehicles that are received from each vehicle, and identifies the remaining work based on the result of the simulation.

6. The operation management system according to claim 1,
wherein the operation planning section reassigns a portion of the remaining work of a corresponding one of the vehicles to another corresponding one of the vehicles according to the remaining battery level of each vehicle, and re-creates the operation plan in such a manner that the remaining work other than the reassigned portion is performed by the vehicle that is determined by the operation plan monitoring section to be unable to complete the operation plan.

7. The operation management system according to claim 1,
wherein the operation planning section re-creates the operation plan in such a manner that the remaining work of traveling between locations which has not been performed by the vehicle that is determined by the operation plan monitoring section to be unable to complete the operation plan is reassigned to a plurality of other vehicles according to the remaining battery level of each vehicle.

8. The operation management system according to claim 1,
wherein the operation planning section re-creates the operation plan in such a manner that the remaining work of traveling between locations which has not been performed by a plurality of the vehicles that are determined by the operation plan monitoring section to be unable to complete the operation plan is reassigned to one other vehicle according to the remaining battery level of each vehicle.

9. The operation management system according to claim 1,
wherein the operation planning section re-creates the operation plan in such a manner that the remaining work of traveling between locations which has not been performed by a plurality of the vehicles that are determined by the operation plan monitoring section to be unable to complete the operation plan is reassigned to a plurality of other vehicles according to the remaining battery level of each vehicle.

10. An operation management method that is used by an operation management system to manage operations of a plurality of vehicles powered by a battery, the operation management method comprising:
an operation planning step of creating an operation plan for causing each vehicle to perform work of traveling between locations;
an operation plan monitoring step of monitoring the operation of each vehicle that is performed in accordance with the operation plan;
a determination step of determining, according to operating status of each vehicle, whether each vehicle is able to complete the operation plan; and
a re-creation step of re-creating the operation plan in such a manner that remaining work of traveling between locations which has not been performed by a vehicle that is determined by the determination step to be unable to complete the operation plan is reassigned to another vehicle according to the remaining battery level of each vehicle.
